(19) United States
(12) Patent Application Publication
(10) Pub. No.: US 2025/0107138 A1
(43) Pub. Date: Mar. 27, 2025

(54) SEMICONDUCTOR DEVICE AND METHOD FOR MANUFACTURING SEMICONDUCTOR DEVICE

(71) Applicant: ROHM CO., LTD., Kyoto (JP)

(72) Inventors: Kazuhiro TAMURA, Kyoto-shi (JP); Naoki IZUMI, Kyoto-shi (JP)

(73) Assignee: ROHM CO., LTD., Kyoto (JP)

(21) Appl. No.: 18/896,042

(22) Filed: Sep. 25, 2024

(30) Foreign Application Priority Data
Sep. 27, 2023 (JP) 2023-166185

(51) Int. Cl. H01L 29/78; H01L 21/308; H01L 29/10; H01L 29/66

(52) U.S. Cl. CPC H10D 30/65; H01L 21/308; H10D 30/0281; H10D 62/393

(57) ABSTRACT

A semiconductor device includes a semiconductor substrate having a first conductivity type; a gate electrode positioned on the semiconductor substrate; and a semiconductor part embedded in the semiconductor substrate and having the first conductivity type, in which the semiconductor substrate is provided with at least a part of a drift region being adjacent to the semiconductor part and having a second conductivity type, and a surface of the semiconductor part and a first portion included in a surface of the drift region are positioned higher than a second portion in a surface of the semiconductor substrate, the second portion being positioned below the gate electrode.

### CROSS REFERENCE TO RELATED APPLICATIONS

This application claims the benefit of priority to Japanese Patent Application No. 2023-166185 filed on Sep. 27, 2023. The entire contents of the above-identified application are hereby incorporated by reference.

### TECHNICAL FIELD

The present disclosure relates to a semiconductor device and a method for manufacturing the semiconductor device.

### BACKGROUND

Japanese Unexamined Patent Publication No. 2016-27622 discloses a semiconductor device provided with a substrate, a first transistor provided on the substrate, and a second transistor provided on the substrate. Each of the first transistor and the second transistor includes a well of a first conductivity type and a band-shaped region provided on the well and extending in a first direction, the band-shaped region includes a back gate region of the first conductivity type and a source region of a second conductivity type, and a ratio of a length of the source region to a length of the back gate region along the first direction in the band-shaped region of the first transistor is greater than a ratio in the band-shaped region of the second transistor.

### BRIEF DESCRIPTION OF THE DRAWINGS

FIG. 1 is a plan view illustrating a chip of a semiconductor device according to an embodiment;

FIG. 2 is a schematic cross-sectional view of a principle part of the semiconductor device according to the embodiment;

FIG. 3A is a schematic cross-sectional view for explaining a part of a method for manufacturing the semiconductor device according to the embodiment;

FIG. 3B is a schematic cross-sectional view for explaining a part of the method for manufacturing the semiconductor device according to the embodiment;

FIG. 3C is a schematic cross-sectional view for explaining a part of the method for manufacturing the semiconductor device according to the embodiment;

FIG. 3D is a schematic cross-sectional view for explaining a part of the method for manufacturing the semiconductor device according to the embodiment;

FIG. 4 is a schematic cross-sectional view illustrating the configuration of a semiconductor device according to a modification;

FIG. 5A is a schematic cross-sectional view for explaining a part of a method for manufacturing the semiconductor device according to the modification;

FIG. 5B is a schematic cross-sectional view for explaining a part of the method for manufacturing the semiconductor device according to the modification;

FIG. 5C is a schematic cross-sectional view for explaining a part of the method for manufacturing the semiconductor device according to the modification;

FIG. 5D is a schematic cross-sectional view for explaining a part of the method for manufacturing the semiconductor device according to the modification; and

FIG. 5E is a schematic cross-sectional view for explaining a part of the method for manufacturing the semiconductor device according to the modification.

### DETAILED DESCRIPTION

Hereinafter, embodiments of the present disclosure will be described in detail with reference to the accompanying drawings. In the following description, the same reference numerals will be used for the same elements or elements having the same functions, and redundant description will be omitted. The word “identical” and words similar thereto in the present specification are not limited merely to “completely identical”. In addition, since the drawings are for conceptually describing the embodiments, the dimensions of the respective components represented and the ratios thereof may be different from the actual ones.

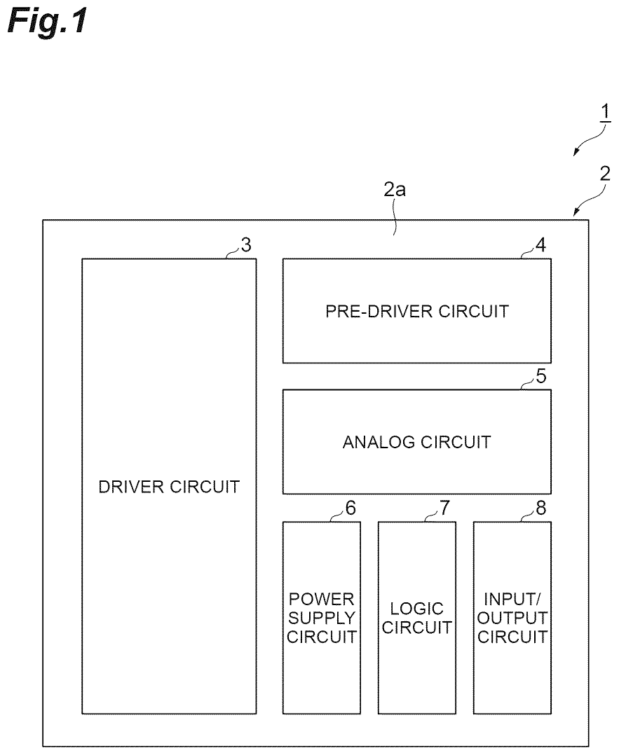

FIG. 1 is a plan view illustrating a chip of a semiconductor device according to the present embodiment. As illustrated in FIG. 1, a semiconductor device 1 includes a chip 2 (semiconductor chip) made of silicon and having a rectangular parallelepiped shape. The chip 2 is one of a plurality of devices formed on a silicon wafer having a diameter of 300 mm (about 12 inches), for example. Hereinafter, the direction along the thickness of the chip 2 may be simply referred to as a thickness direction, and a surface 2a of the chip 2 illustrated in FIG. 1 may be referred to as an upper surface of the chip 2.

The chip 2 has the surface 2a provided with device regions such as a driver circuit 3, a pre-driver circuit 4, an analog circuit 5, a power supply circuit 6, a logic circuit 7, and an input/output circuit 8. At least one of the device regions includes a functional device formed by using regions inside and outside the chip 2. The functional device includes, for example, at least one of a semiconductor switching device, a semiconductor rectifying device, or a passive device. The functional device may include a circuit network formed in combination of at least two of a semiconductor switching device, a semiconductor rectifying device, or a passive device. Although not illustrated, a metal wiring or other conductive materials can be provided above the surface 2a of the chip 2.

The semiconductor switching device includes, for example, at least one of a metal insulator semiconductor field effect transistor (MISFET), a bipolar junction transistor (BJT), an insulated gate bipolar junction transistor (IGBT), or a JFET. The semiconductor rectifying device may include at least one of a pn junction diode, a pin junction diode, a Zener diode, a Schottky barrier diode, or a fast recovery diode. The passive device may include at least one of a resistor, a capacitor, an inductor, or a fuse.

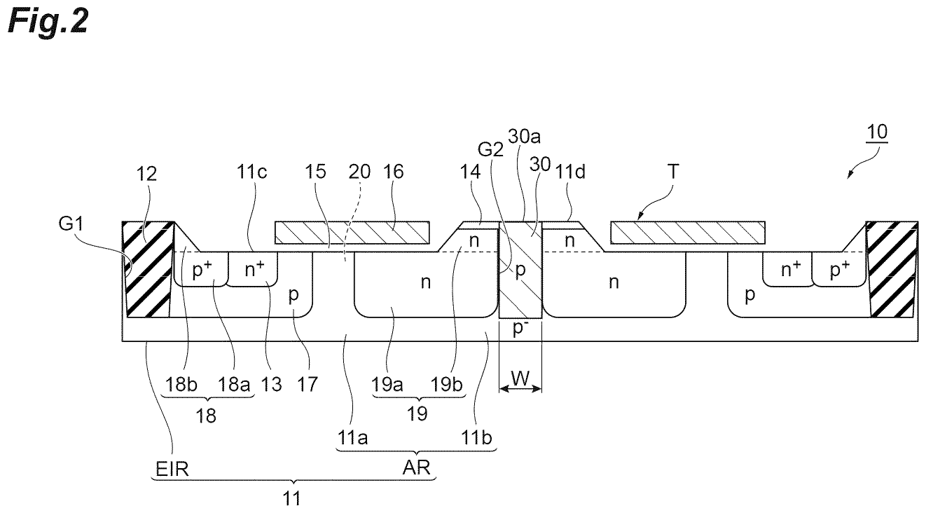

At least one of the device regions includes at least one transistor region 10 (see FIG. 2 described later). The transistor region 10 includes an FET structure (transistor structure). In the present embodiment, the FET structure has a so-called lateral double diffused MISFET (LDMISFET) structure. Hereinafter, an example of the FET structure included in the semiconductor device 1 will be described.

FIG. 2 is a schematic cross-sectional view of a principle part of the semiconductor device according to the present embodiment. As illustrated in FIG. 2, a semiconductor substrate 11 is a high-resistance silicon substrate that is the silicon wafer, and has a first conductivity type. In the present embodiment, the first conductivity type is p-type, or may be n-type. The impurity concentration of the semiconductor substrate 11 is set to a relatively low value. In the present embodiment, the impurity concentration of the semiconductor substrate 11 is, for example, 1.0×10¹³ cm⁻³ or more and 1.0×10¹⁴ cm⁻³ or less. The potential of the semiconductor substrate 11 is, for example, a reference potential, but the present embodiment is not limited thereto. The semiconductor substrate 11 may be grounded. FIG. 2 illustrates an element isolation region EIR and an active region AR in the semiconductor substrate 11.

The element isolation region EIR includes a region where a shallow trench isolation (STI) structure is provided as an element isolation structure. The STI structure includes a trench G1 and an insulating layer 12 embedded into the trench G1. The trench G1 extends from the upper surface to the lower surface of the semiconductor substrate 11 along the thickness direction. A part of the semiconductor substrate 11 is removed by etching to form the trench G1. The insulating layer 12 is an insulator provided in the trench G1. The insulating layer 12 is, for example, an oxide film formed by a chemical vapor deposition method (CVD method).

The active region AR is a region where the FET structure is provided, and is defined by, for example, the element isolation region EIR. The active region AR is provided with one or more transistors T. A portion included in the active region AR in the semiconductor substrate 11 includes a first substrate portion 11a and a second substrate portion 11b thicker than the first substrate portion 11a. The thickness of the first substrate portion 11a is smaller than the thickness of the second substrate portion 11b in the thickness direction, and a surface 11c of the first substrate portion 11a is positioned lower than a surface 11d of the second substrate portion 11b. Therefore, a part of the second substrate portion 11b can be regarded as a protrusion that protrudes upward in the thickness direction with respect to the first substrate portion 11a. For example, a part of the semiconductor substrate 11 is thinned by etching or other ways to provide the first substrate portion 11a and the second substrate portion 11b. In the present embodiment, the first substrate portion 11a surrounds the second substrate portion 11b in plan view, but the present embodiment is not limited thereto.

Each of the transistors T includes a source region 13 having a second conductivity type different from the first conductivity type, a drain region 14 having the second conductivity type, a gate insulating layer 15, and a gate electrode 16. The source region 13 and the drain region 14 are included in the active region AR. The source region 13 is provided within the first substrate portion 11a, and the drain region 14 is provided within the second substrate portion 11b. The gate insulating layer 15 and the gate electrode 16 are positioned on and above the semiconductor substrate 11.

The source region 13 is a region that functions as a source of the transistor T. The source region 13 constitutes a part of the surface 11c of the first substrate portion 11a. In the present embodiment, the source region 13 is an n-type region and is fixed at a source potential. For example, the source potential is applied to the source region 13 from the outside of the chip 2. The impurity concentration of the source region 13 is, for example, 1.0×10¹⁸ cm⁻³ or more and 1.0×10²¹ cm⁻³ or less. A body region 17 and a contact region 18 are provided around the source region 13 and are in contact with the source region 13.

The body region 17 is, for example, a region (well region) that covers the bottom portion of the source region 13 and that has the first conductivity type, and extends along the peripheral edge of the active region AR. The body region 17 has, for example, an annular shape, an elliptical annular shape, or other shapes in plan view. The body region 17 constitutes a part of the surface 11c of the first substrate portion 11a. The body region 17 includes a first region that is positioned closer to the drain region 14 than the source region 13 in plan view. The body region 17 includes a second region that is positioned below the source region 13. The body region 17 includes a third region that is positioned closer to the element isolation region EIR than the source region 13 in plan view. The third region is in contact with the element isolation region EIR, but the present embodiment is not limited thereto. The depth of the body region 17 is, for example, about the same as that of the trench G1. The difference between the depth of the body region 17 and the depth of the trench G1 is, for example, 20% or less. From the viewpoint of element isolation, the depth of the body region 17 may be shallower than the depth of the trench G1. In the present embodiment, the body region 17 is fixed at the potential (for example, a back gate potential) of the semiconductor substrate 11, but the present embodiment is not limited thereto. The impurity concentration of the body region 17 is higher than the impurity concentration of the semiconductor substrate 11, and for example, 1.0×10¹⁵ cm⁻³ or more and 1.0×10¹⁸ cm⁻³ or less.

The contact region 18 is a region fixed at a potential different from that of the source region 13, and has the first conductivity type. The contact region 18 is positioned in the body region 17, is in contact with the source region 13, and is positioned outside the source region 13. The contact region 18 includes a first region 18a that is provided within the first substrate portion 11a of the semiconductor substrate 11, and a second region 18b that is provided within the second substrate portion 11b of the semiconductor substrate 11. Therefore, the first region 18a constitutes a part of the surface 11c of the first substrate portion 11a, and the second region 18b constitutes a part of the surface 11d of the second substrate portion 11b. The second region 18b of the contact region 18 overlaps with the third region of the body region 17. Therefore, the second region 18b is in contact with the element isolation region EIR, but the present embodiment is not limited thereto. The impurity concentration of the contact region 18 is higher than the impurity concentration of the body region 17. For instance, the impurity concentration of the contact region 18 is, for example, 1.0×10¹⁸ cm⁻³ or more and 1.0×10²¹ cm⁻³ or less.

The drain region 14 is a region that functions as a drain of the transistor T, and a drain potential is applied thereto. The drain region 14 has, for example, a circular shape, an elliptical circular shape, or other shapes in plan view. The drain region 14 constitutes a part of the surface 11d of the second substrate portion 11b. Therefore, the drain region 14 constitutes a part of the uppermost portion of the second substrate portion 11b and is positioned higher than the source region 13. The impurity concentration of the drain region 14 is, for example, 1.0×10¹⁸ cm⁻³ or more and 1.0×10²¹ cm⁻³ or less. A drift region 19 that is in contact with the drain region 14 and separated from the body region 17 is provided below the drain region 14 in the active region AR.

The drift region 19 is a region (well region) that covers the bottom portion of the drain region 14 and has the second conductivity type. As a result, the drift region 19 includes a region that forms a pn junction with respect to the semiconductor substrate 11. The drift region 19 and the semiconductor substrate 11 form a pn junction portion, thereby increasing the breakdown voltage of the transistor T. The drift region 19 has, for example, a shape surrounding the drain region 14 in plan view. The impurity concentration of the drift region 19 is higher than the impurity concentration of the semiconductor substrate 11, and for example, 1.0×10¹⁵ cm⁻³ or more and 1.0×10¹⁸ cm⁻³ or less.

In the present embodiment, whole of the drift region 19 is provided in the semiconductor substrate 11. The drift region 19 includes a first region 19a and a second region 19b positioned above the first region 19a. The first region 19a is provided across the first substrate portion 11a and the second substrate portion 11b of the semiconductor substrate 11. A part of the first region 19a is positioned closer to the source region 13 than the second region 19b. The second region 19b is in contact with the drain region 14 and provided within the second substrate portion 11b of the semiconductor substrate 11. The second region 19b is positioned between the drain region 14 and the first region 19a in the thickness direction. A part of the second region 19b is covered with the drain region 14. Therefore, the part of the first region 19a constitutes a part of the surface 11c of the first substrate portion 11a, and a part of the second region 19b constitutes a part of the surface 11d of the second substrate portion 11b. Therefore, the part (first portion) of the second region 19b is positioned higher than the surface 11c of the first substrate portion 11a. The part of the second region 19b includes an inclined surface extending to approach the surface 11c of the first substrate portion 11a as the part is away from the drain region 14, but the present invention is not limited thereto.

The gate insulating layer 15 is an insulation that selectively covers the semiconductor substrate 11. In the present embodiment, the gate insulating layer 15 covers at least the first substrate portion 11a of the semiconductor substrate 11. The gate insulating layer 15 includes, for example, a local oxidation of silicon (LOCOS) film formed by selective oxidation on the surface of the semiconductor substrate 11, an oxide film, a nitride film, an oxynitride film, and other films selectively formed on the semiconductor substrate 11. The gate insulating layer 15 may have a single layer structure or a multilayer structure.

The gate electrode 16 is an electrode that is positioned above the semiconductor substrate 11, with the gate insulating layer 15 interposed therebetween. The gate electrode 16 at least overlaps with a channel region 20 formed between the body region 17 and the drift region 19. A current path is formed, along which a current passes through the body region 17, the drift region 19, and the channel region 20 between the source region 13 and the drain region 14 according to a potential applied to the gate electrode 16. In the present embodiment, the gate electrode 16 overlaps with the first region of the body region 17 and the first region 19a of the drift region 19. Therefore, a portion (second portion) positioned below the gate electrode 16 on the surface of the semiconductor substrate 11 is positioned lower than the second region 19b of the drift region 19. The gate electrode 16 includes, for example, polycrystalline silicon into which impurities are introduced.

The active region AR is provided with a semiconductor part 30 that is embedded in the semiconductor substrate 11 and has the first conductivity type. The semiconductor part 30 includes a part that forms a pn junction with respect to the drift region 19, and is, for example, polycrystalline silicon into which impurities are introduced. The semiconductor part 30 is embedded in a trench G2 provided within the second substrate portion 11b of the semiconductor substrate 11. The trench G2 is formed, for example, at a different timing from the trench G1, but the present embodiment is not limited thereto. The depth of the trench G2 is, for example, about the same as the depth of the trench G1, but the present embodiment is not limited thereto. In the present embodiment, the depth of the semiconductor part 30 embedded into the trench G2 is about the same as the depth of the drift region 19. The trench G2 is provided to be adjacent to the drain region 14 and the drift region 19. Therefore, the semiconductor part 30 embedded into the trench G2 is adjacent to at least the drift region 19. In the present embodiment, the semiconductor part 30 is adjacent to both the first region 19a and the second region 19b of the drift region 19. As a result, the RESURF effect by the semiconductor part 30 being provided is favorably exhibited. The semiconductor part 30 includes a surface 30a that constitutes a part of the surface of the second substrate portion 11b, and substantially coincides with a surface of the drain region 14. Therefore, the surface 30a is positioned higher than the surface 11c of the first substrate portion 11a.

Although not illustrated, the shape of the semiconductor part 30 in plan view has a substantially rectangular shape, a substantially elliptical shape, or other shapes. In FIG. 2, the width of the semiconductor part 30 along the direction in which the source region 13 and the contact region 18 are aligned side by side is 0.5 μm or more and 1 μm or less, for example. This direction corresponds to the lateral width direction of the semiconductor part 30 in plan view. Therefore, a lateral width W of the semiconductor part 30 is, for example, 0.5 μm or more and 1 μm or less.

From the viewpoint of favorably exhibiting the RESURF effect, the difference between the depth of the semiconductor part 30 and the depth of the drift region 19 is, for example, 10% or less. The semiconductor part 30 is fixed at the potential of the semiconductor substrate 11, for example. The impurity concentration of the semiconductor part 30 is higher than the impurity concentration of the semiconductor substrate 11, and for example, 1.0×10¹⁵ cm⁻³ or more and 1.0×10¹⁸ cm⁻³ or less. In order to favorably exhibit the RESURF effect, the difference between the impurity concentration of the semiconductor part 30 and the impurity concentration of the drift region 19 is, for example, 10% or less.

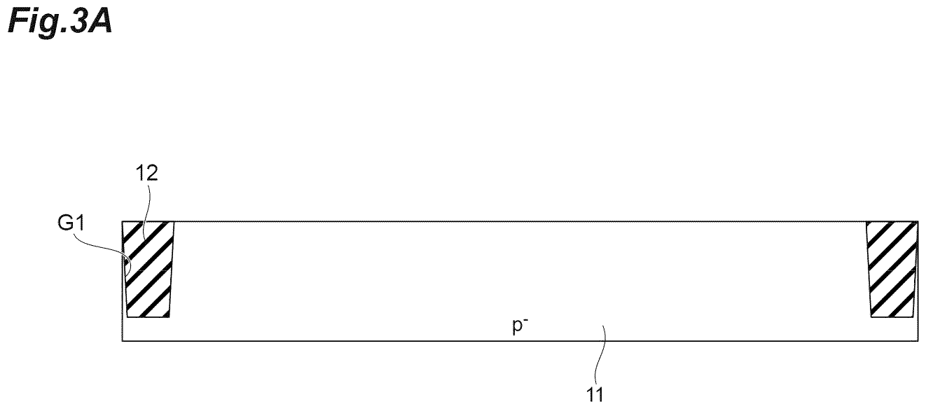

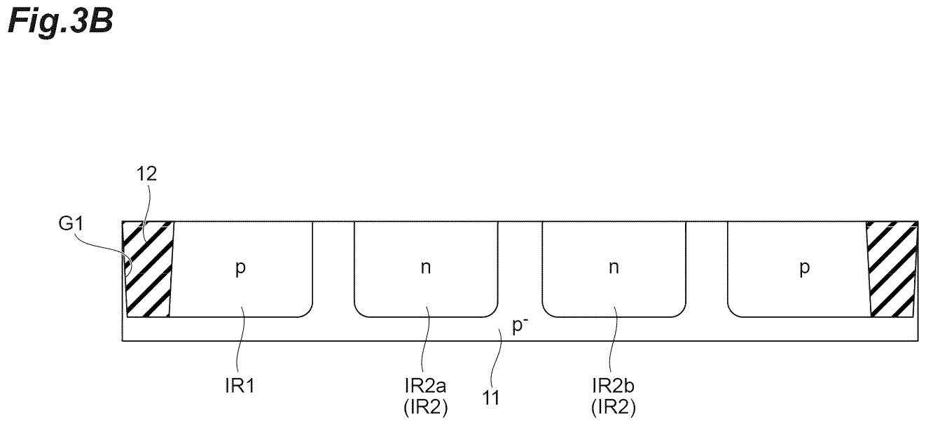

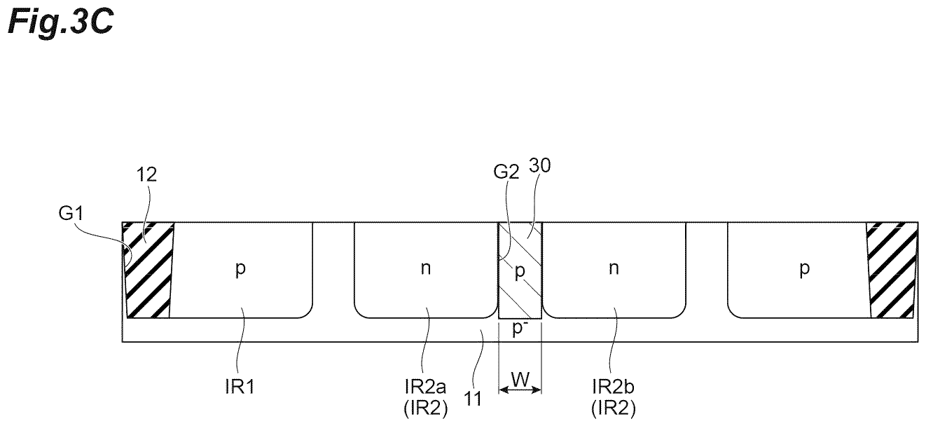

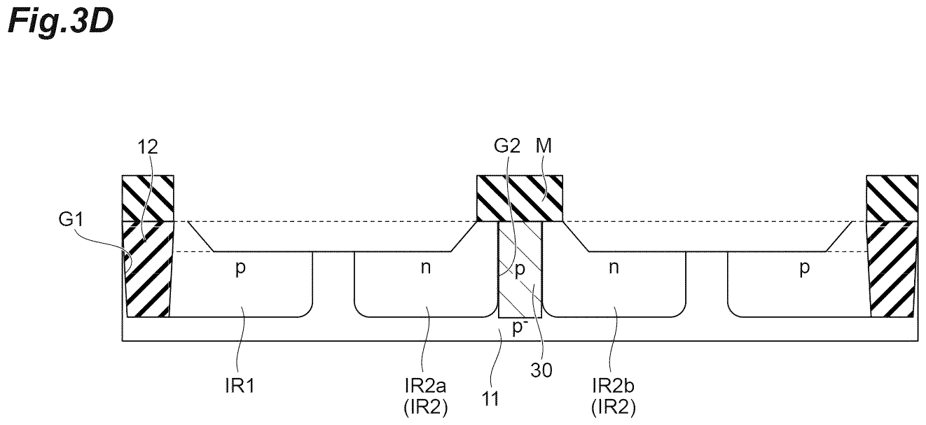

Next, an example of a method for manufacturing the semiconductor device according to the present embodiment will be described with reference to FIGS. 3A to 3D. FIGS. 3A to 3D are schematic cross-sectional views for explaining a part of the method for manufacturing the semiconductor device according to the present embodiment. Hereinbelow, an example of a method for manufacturing a transistor region 10 according to the present embodiment will be described with reference to FIGS. 3A to 3D.

First, as illustrated in FIG. 3A, the trench G1 is formed in the semiconductor substrate 11 having the first conductivity type, and thereafter, the insulating layer 12 is embedded into the trench G1 (step 1). At step 1, for example, the trench G1 having a desired planar shape is formed in the semiconductor substrate 11 by dry etching or other ways using a mask (not illustrated). Subsequently, an insulator is embedded into the trench G1 by a CVD method or other methods. As a result, the insulating layer 12 embedded into the trench G1 is formed. The insulator provided other than the trench G1 is removed by, for example, chemical mechanical polishing (CMP), wet etching, or other ways.

Next, as illustrated in FIG. 3B, an impurity region IR1 having the first conductivity type and an impurity region IR2 having the second conductivity type are formed in the semiconductor substrate 11 (step 2). At step 2, for example, the impurity region IR1 is formed in a part of the semiconductor substrate 11 by ion implantation using a mask (not illustrated), and thereafter, the impurity region IR2 is formed in the other part of the semiconductor substrate 11 by ion implantation using a mask different from the mask. At step 2, the impurity region IR2 may be formed in a part of the semiconductor substrate 11, followed by the formation of the impurity region IR1 in the other part of the semiconductor substrate 11. An impurity concentration of each of the impurity regions IR1 and IR2 is higher than the impurity concentration of the semiconductor substrate 11, and for example, 1.0×10¹⁸ cm⁻³ or more and 1.0×10²¹ cm⁻³ or less. In FIG. 3B and subsequent figures, one of the impurity regions IR2 is referred to as a first impurity region IR2a, and the other of the impurity regions IR2 is referred to as a second impurity region IR2b.

Next, as illustrated in FIG. 3C, the trench G2 is formed in a region adjacent to the impurity region IR2 in the semiconductor substrate 11, and thereafter, the semiconductor part 30 having the first conductivity type is embedded into the trench G2 (step 3). At step 3, for example, the trench G2 is formed in the semiconductor substrate 11 by dry etching or other ways using a mask (not illustrated). In the present embodiment, the region surrounded by the impurity region IR2 in the semiconductor substrate 11 in plan view is thinned by etching or other ways. Subsequently, impurities and a semiconductor are embedded into the trench G2 by a CVD method or other methods. As a result, the semiconductor part 30 embedded into the trench G2 and adjacent to the impurity region IR2 is formed. In the present embodiment, the semiconductor part 30 surrounded by the impurity region IR2 in plan view is formed. In FIG. 3C, the lateral width W of the semiconductor part 30 corresponding to the interval between the first impurity region IR2a and the second impurity region IR2b is, for example, about 0.5 μm or more and 1 μm.

Next, as illustrated in FIG. 3D, a mask M that covers at least a part of the impurity region IR2 and at least the semiconductor part 30 is formed, and thereafter, the portion of the semiconductor substrate 11 exposed from the mask M is thinned by etching (step 4). At step 4, first, the mask M is formed over the semiconductor substrate 11. The mask M may be a resist mask, a silicon oxide film, or other materials. In the present embodiment, the mask M that covers whole of the insulating layer 12, whole of the semiconductor part 30, and a part of the impurity region IR2 is formed. The part of the impurity region IR2 includes at least a portion of the impurity region IR2 adjacent to the semiconductor part 30. On the other hand, the impurity region IR1 in the semiconductor substrate 11 is exposed from the mask M. Subsequently, the portion of the semiconductor substrate 11, which is not covered with the mask M, is thinned by etching using the mask M. As a result, the body region 17 and the drift region 19 are formed by thinning of the entire impurity region IR1 and the part of the impurity region IR2, respectively, and the first substrate portion 11a and the second substrate portion 11b of the semiconductor substrate 11 are formed. In the present embodiment, the thickness of the portion of the semiconductor substrate 11 exposed from the mask M may be as large as the thickness close to the mask M. As a result, the second region 18b of the contact region 18 and other regions are formed.

Next, the transistor T illustrated in FIG. 2 is manufactured through the following steps. A specific example includes the followings: first, removing the mask M, and then performing multiple ion implantation. As a result, the source region 13 and the contact region 18 are formed in the body region 17, and the drain region 14 is formed in the drift region 19. The source region 13 and the drain region 14 may be formed, followed by the formation of the contact region 18, or the contact region 18 may be formed, followed by the formation of the source region 13 and the drain region 14. Subsequently, the gate insulating layer 15 is formed on the semiconductor substrate 11, followed by the formation of the gate electrode 16 above the thinned first substrate portion 11a (more specifically, on the gate insulating layer 15 overlapping with the first substrate portion 11a) of the semiconductor substrate 11. For example, the gate insulating layer 15 is formed by oxidization on an exposed surface of the semiconductor substrate 11. Then, for example, a polycrystalline silicon layer formed on the gate insulating layer 15 is patterned to form the gate electrode 16. As described above, the transistor T is formed. After the formation of the transistor T, wiring and other components can be appropriately formed over the transistor T. The ion implantation may be performed after the formation of the gate insulating layer 15 and the gate electrode 16. In other words, in the formation of the transistor T, the source region 13, the drain region 14, and the contact region 18 may be formed after the gate insulating layer and the gate electrode 16 are formed.

The operational effects exhibited by the semiconductor device 1 according to the present embodiment described above will be described using the transistors according to the following two reference examples.

A transistor according to a first reference example has the same configuration as that of the transistor T, except that the trench G2 and the semiconductor part 30 are not provided. That is, in the transistor according to the first reference example, a part of the semiconductor substrate 11 is positioned between the first impurity region IR2a and the second impurity region IR2b. In addition, a transistor according to a second reference example has the same configuration as that of the transistor T except that an impurity region having the first conductivity type is formed in the region positioned between the first impurity region IR2a and the second impurity region IR2b in the semiconductor substrate 11. The impurity concentration of the impurity region in the second reference example is higher than the impurity concentration of the semiconductor substrate 11, and is, for example, similar to the impurity concentration of the first impurity region IR2a and the second impurity region IR2b.

In the first reference example, from the viewpoint of the impurity concentration of the semiconductor substrate 11 and the expansion of a depletion layer, it is necessary to secure the size of the region positioned between the first impurity region IR2a and the second impurity region IR2b in the semiconductor substrate 11 to some extent. For example, the width of the region corresponding to the interval between the first impurity region IR2a and the second impurity region IR2b is necessary to ensure at least 5 μm or more. In order to form the impurity region having the first conductivity type between the first impurity region IR2a and the second impurity region IR2b in the second reference example, it is necessary to set the interval between the first impurity region IR2a and the second impurity region IR2b to at least several μm or more (for example, 3 μm or more).

On the other hand, in the method for manufacturing the semiconductor device 1 according to the present embodiment, the trench G2 is formed between the first impurity region IR2a and the second impurity region IR2b, and the semiconductor part 30 that is embedded into the trench G2 and has the first conductivity type is formed. In this case, the semiconductor part 30 can be formed even though the interval between the first impurity region IR2a and the second impurity region IR2b is, for example, 1 μm or less. Therefore, in the present embodiment, the miniaturization of the transistor T can be achieved as compared to the first and second reference examples. In addition, in the present embodiment, the surface 30a of the semiconductor part 30 and the part of the second region 19b of the drift region 19 are positioned higher than the surface 11c of the first substrate portion 11a of the semiconductor substrate 11. As a result, the drift region 19 and the semiconductor part can be made to protrude above the surface 11c. In this case, as compared to a case where a surface of a semiconductor substrate is simply a smooth surface, the region where the drift region 19 and the semiconductor part 30 are in contact with each other can be enlarged, and the RESURF effect can be more favorably exhibited. Therefore, the breakdown voltage of the transistor T can be ensured.

As the example, the semiconductor substrate 11 is provided with whole of the drift region 19 and the drain region 14 positioned on the second region 19b of the drift region 19 and having the second conductivity type. In this case, as compared to the case where a surface of a semiconductor substrate is simply a smooth surface, the length of the current path between the source region 13 and the drain region 14 can be lengthened, resulting in an enhancement on the breakdown voltage of the transistor T.

As the example, the difference between the depth of the drift region 19 and the depth of the semiconductor part 30 is 10% or less. In this case, the charge balance between the drift region 19 and the semiconductor part 30 is less prone to disruption, so that the RESURF effect can be stably exhibited.

As the example, the impurity concentration of the semiconductor part 30 and the impurity concentration of the drift region 19 are higher than the impurity concentration of the semiconductor substrate 11. In this case, the RESURF effect can be stably exhibited.

As the example, the difference between the impurity concentration of the semiconductor part 30 and the impurity concentration of the drift region 19 is 10% or less. In this case, the charge balance between the drift region 19 and the semiconductor part 30 is less prone to disruption, so that the RESURF effect can be stably exhibited. As the example, the lateral width W of the semiconductor part 30 in plan view is 0.5 μm or more and 1 μm or less. Even in this case, since the semiconductor part 30 can be favorably formed, it is possible to provide the semiconductor device 1 capable of achieving miniaturization while ensuring the breakdown voltage.

Hereinafter, a modification of the above embodiment will be described. In the description of the modification, the redundant description with the above-described embodiment will be omitted, and different points will be described. That is, the description of the embodiment described above may be appropriately used for the modification within a technically feasible range.

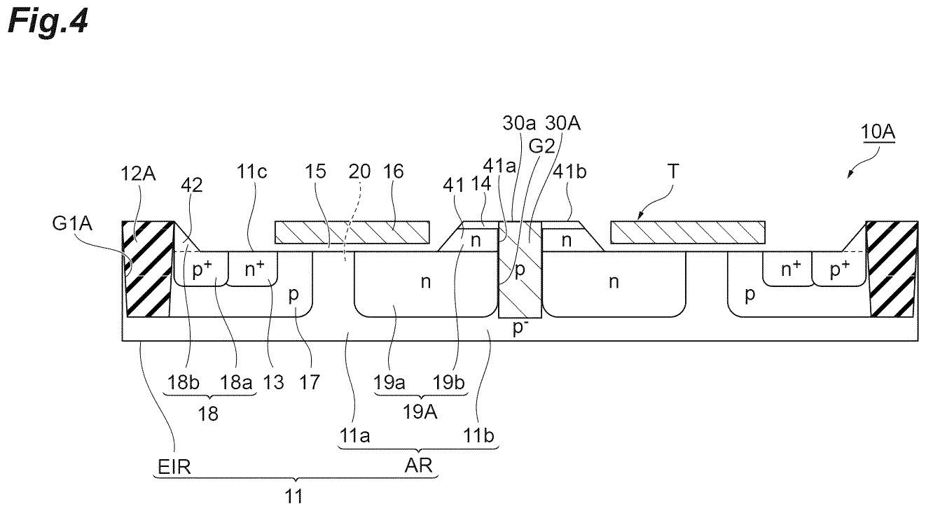

FIG. 4 is a schematic cross-sectional view of a principle part of a semiconductor device according to the modification. As illustrated in FIG. 4, a transistor region 10A according to the modification is different from the transistor region 10 of the above-described embodiment in that a semiconductor substrate 11 and semiconductor layers 41 and 42 are mainly provided. Each of the semiconductor layers 41 and 42 is formed, for example, by removing a part of an epitaxial semiconductor layer grown on the semiconductor substrate 11. The semiconductor layer 41 constitutes a second region 19b of a drift region 19A, and has a second conductivity type. Therefore, in the present modification, the drift region 19A is provided across the semiconductor substrate 11 and the semiconductor layer 41. A semiconductor part 30A is embedded across a trench G2 provided in the semiconductor substrate 11 and an opening 41a provided in the semiconductor layer 41 and overlapping with the trench G2. Therefore, the semiconductor part 30A is in contact with not only the semiconductor substrate 11 but also the semiconductor layer 41. In the present modification, the surface 30a of the semiconductor part 30 and a top surface 41b of the semiconductor layer 41 are continuously connected to each other, but the present modification is not limited thereto. The top surface 41b of the semiconductor layer 41 is a portion (first portion) positioned higher than a surface 11c of the semiconductor substrate 11. The semiconductor layer 42 constitutes a second region 18b of a contact region 18, and has a first conductivity type.

In an element isolation region EIR of the present modification, a trench GIA is formed across the semiconductor substrate 11 and the semiconductor layer 42, and an insulating layer 12A is embedded into the trench GIA.

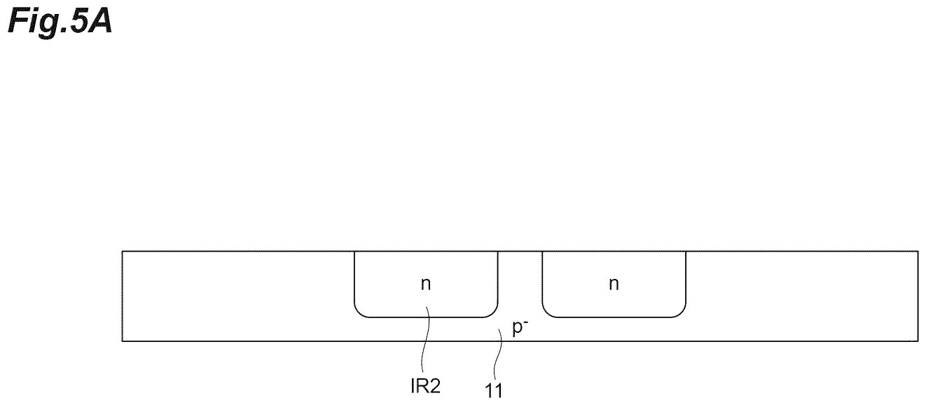

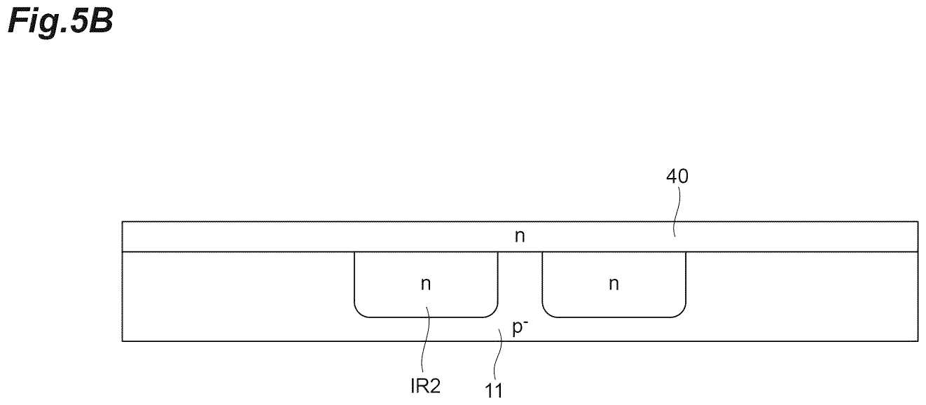

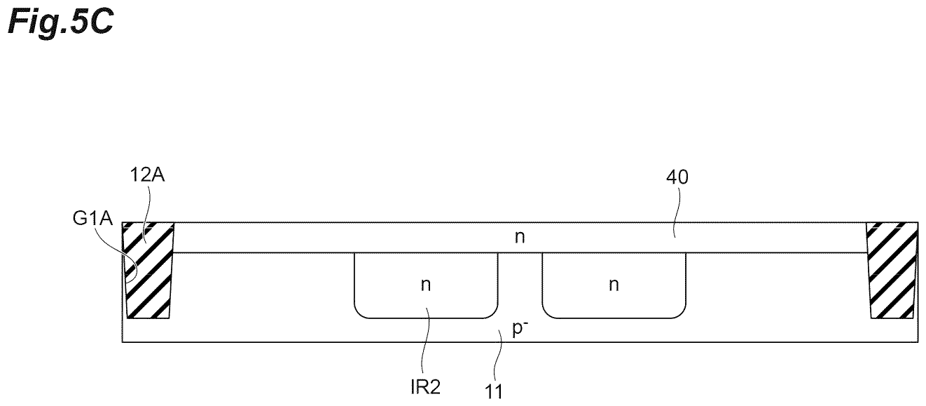

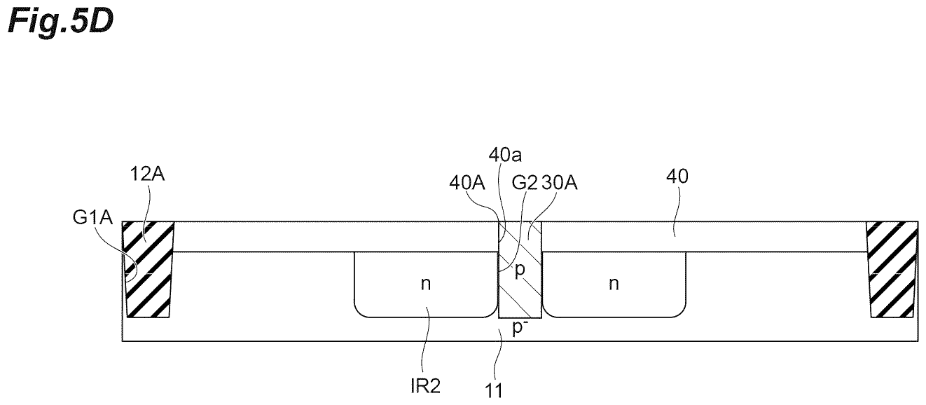

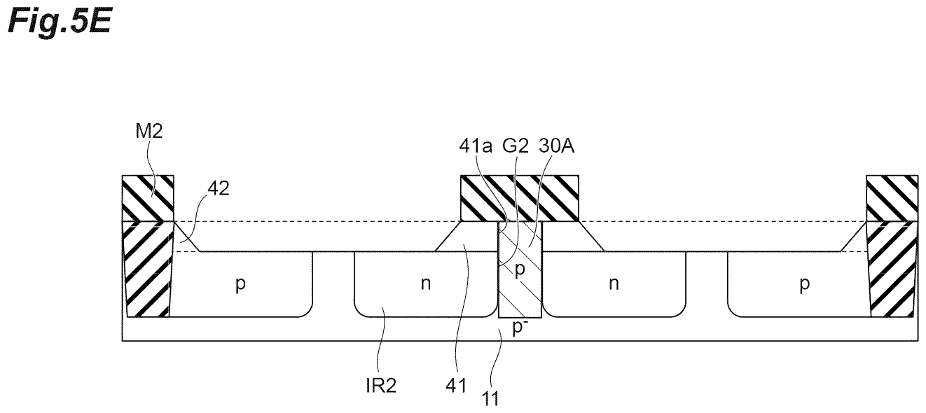

Next, an example of a method for manufacturing the semiconductor device according to the present modification will be described with reference to FIGS. 5A to 5E. FIGS. 5A to 5E are schematic cross-sectional views for explaining a part of the method for manufacturing the semiconductor device according to the present modification. Hereinbelow, an example of a method for manufacturing the transistor region 10A according to the present modification will be described with reference to FIGS. 5A to 5E.

First, as illustrated in FIG. 5A, an impurity region IR2 having the second conductivity type is formed in the semiconductor substrate 11 (step 1A). At step 1A, for example, the impurity region IR2 is formed in a part of the semiconductor substrate 11 by ion implantation using a mask (not illustrated).

Nest, as illustrated in FIG. 5B, a semiconductor layer 40 having the second conductivity type is formed on the semiconductor substrate 11 (step 2A). At step 2A, the semiconductor layer 40 is formed on the surface of the semiconductor substrate 11 by, for example, an epitaxial growth method. The thickness of the semiconductor layer 40 is, for example, 200 nm or more and 400 nm or less.

Next, as illustrated in FIG. 5C, the trench GIA is formed across the semiconductor substrate 11 and the semiconductor layer 40, and thereafter, the insulating layer 12A is embedded into the trench GIA (step 3A). At step 3A, the trench GIA and the insulating layer 12A are formed by the same method as step 1 of the above-described embodiment, except that a mask (not illustrated) is formed on the semiconductor layer 40, and a part of the semiconductor layer 40 is etched in addition to the semiconductor substrate 11.

Next, as illustrated in FIG. 5D, a trench G2A is formed in a region adjacent to the impurity region IR2 in the semiconductor substrate 11, and an opening 40a is formed within a portion overlapping with the trench G2 in the semiconductor layer 40 (step 4A). At step 4A, for example, the opening 40a is formed in the semiconductor layer 40, and the trench G2 is formed in the semiconductor substrate 11 by dry etching or other ways using a mask (not illustrated) provided on the semiconductor layer 40. Subsequently, impurities and a semiconductor are embedded across the trench G2 and the opening 40a by a CVD method or other methods. As a result, the semiconductor part 30A embedded into the trench G2 and adjacent to the impurity region IR2 and the semiconductor layer 40 is formed. A lateral width of the semiconductor part 30A is about the same as the lateral width W of the semiconductor part 30 of the above-described embodiment.

Next, as illustrated in FIG. 5E, a mask M2 that covers at least a part of the semiconductor layer 40 overlapping with the impurity region IR2 is formed, and thereafter, the portion of the semiconductor layer 40, which is not covered with the mask M2, is removed (step 5A). At step 5A, first, the mask M2 is formed on the semiconductor layer 40 and the insulating layer 12A. The shape of the mask M2 is, for example, similar to the shape of the mask M of the above-described embodiment. Subsequently, the portion of the semiconductor layer 40, which is not covered with the mask M2, is thinned by etching using the mask M2. As a result, the semiconductor layers 41 and 42 are formed, and the drift region 19A is also formed.

Next, the transistor region 10A illustrated in FIG. 4 is manufactured through the following steps. A specific example includes the followings: first, removing the mask M2; then forming a source region 13 and a body region 17 in the semiconductor substrate 11 by multiple ion implantation; forming the contact region 18 across the semiconductor substrate 11 and the semiconductor layer 42; and forming the drain region 14 in the drift region 19A. In the present modification, the formation order of the source region 13, the drain region 14, the body region 17, and the contact region 18 is not particularly limited. Subsequently, similarly to the above-described embodiment, a gate insulating layer 15 and a gate electrode 16 are sequentially formed to form the transistor region 10A. In the present modification, the gate electrode 16 is formed above the exposed portion of the semiconductor layer 40 in the semiconductor substrate 11. In other words, the gate electrode 16 is formed above the portion of the semiconductor substrate 11 that does not overlap with the semiconductor layers 41 and 42.

In the modification described above, the same operational effects as those of the above-described embodiment are also obtained.

In the above-described embodiment and the above-described modification, the semiconductor device can be applied to, for example, a power module used for an inverter circuit that drives an electric motor used as a power source of an automobile (including an electric vehicle), a train, an industrial robot, air conditioning equipment, an air compressor, an electric fan, a vacuum cleaner, a dryer, a refrigerator, and other apparatuses. In addition, the semiconductor device can also be applied to a power module used for an inverter circuit of equipment such as a solar cell, a wind power generator, and other power generation equipment. Alternatively, the semiconductor device can also be applied to a circuit module constituting an analog control power supply, a digital control power supply, or other components.

Although the embodiment and the modification according to one aspect of the present disclosure have been described in detail above, these are merely specific examples used to clarify the technical content of the present disclosure, the present disclosure is not construed as being limited to these specific examples, and the scope of the present disclosure is limited only by the appended claims.

Hereinafter, characteristic examples extracted from the description of this specification and drawings will be described.

[A1]

A semiconductor device including:
a semiconductor substrate having a first conductivity type;
a gate electrode positioned on the semiconductor substrate; and
a semiconductor part embedded in the semiconductor substrate and having the first conductivity type, in which
the semiconductor substrate is provided with at least a part of a drift region being adjacent to the semiconductor part and having a second conductivity type, and
a surface of the semiconductor part and a first portion included in a surface of the drift region are positioned higher than a second portion in a surface of the semiconductor substrate, the second portion being positioned below the gate electrode.

[A2]

The semiconductor device according to [A1], in which the semiconductor substrate is provided with whole of the drift region and a drain region positioned on the first portion and having the second conductivity type.

[A3]

The semiconductor device according to [A1], further including a semiconductor layer positioned on the semiconductor substrate and having the second conductivity type, in which
the drift region is provided across the semiconductor substrate and the semiconductor layer, and
the semiconductor layer has a surface corresponding to the first portion.

[A4]

The semiconductor device according to [A3], in which the semiconductor part is embedded into an opening of the semiconductor layer.

[A5]

The semiconductor device according to any one of [A1] to [A4], in which a difference between a depth of the drift region and a depth of the semiconductor part is 10% or less.

[A6]

The semiconductor device according to any one of [A1] to [A5], in which an impurity concentration of the semiconductor part and an impurity concentration of the drift region are higher than an impurity concentration of the semiconductor substrate.

[A7]

The semiconductor device according to any one of [A1] to [A6], in which a difference between an impurity concentration of the semiconductor part and an impurity concentration of the drift region is 10% or less.

[A8]

The semiconductor device according to any one of [A1] to [A7], in which the semiconductor part is grounded.

[A9]

The semiconductor device according to any one of [A1] to [A8], in which a lateral width of the semiconductor part in plan view is 0.5 μm or more and 1 μm or less.

[A10]

A method for manufacturing a semiconductor device, the method including:
forming an impurity region having a second conductivity type in a semiconductor substrate having a first conductivity type;
forming a trench in a region adjacent to the impurity region in the semiconductor substrate;
embedding a semiconductor part having the first conductivity type into the trench;
forming a mask covering at least a part of the impurity region and the semiconductor part;
thinning a portion of the semiconductor substrate exposed from the mask by etching; and
forming a gate electrode on the portion of the semiconductor substrate, in which the impurity region corresponds to a drift region of a transistor including the gate electrode.

[A11]

A method for manufacturing a semiconductor device, the method including:
forming an impurity region having a second conductivity type in a semiconductor substrate having a first conductivity type;
forming a semiconductor layer having the second conductivity type on the semiconductor substrate;
forming a trench in a region adjacent to the impurity region in the semiconductor substrate and an opening at a portion in the semiconductor layer overlapping with the trench;
embedding a semiconductor part having the first conductivity type across the trench and the opening;
forming a mask covering at least a part of a portion of the semiconductor layer overlapping with the impurity region;
removing a portion of the semiconductor layer exposed from the mask; and
forming a gate electrode on the portion of the semiconductor substrate, in which the impurity region corresponds to a drift region of a transistor including the gate electrode.

[A12]

The method for manufacturing a semiconductor device according to [A10] or [A11], in which a difference between a depth of the drift region and a depth of the semiconductor part is 10% or less.

[A13]

The method for manufacturing a semiconductor device according to any one of [A10] to [A12], in which an impurity concentration of the semiconductor part and an impurity concentration of the drift region are higher than an impurity concentration of the semiconductor substrate.

[A14]

The method for manufacturing a semiconductor device according to any one of [A10] to [A13], in which a difference between an impurity concentration of the semiconductor part and an impurity concentration of the drift region is 10% or less.

[A15]

The method for manufacturing a semiconductor device according to any one of [A10] to [A14], in which a lateral width of the semiconductor part in plan view is 0.5 μm or more and 1 μm or less.

### REFERENCE SIGNS LIST

1 Semiconductor device
2 Chip
2a Surface
3 Driver circuit
4 Pre-driver circuit
5 Analog circuit
6 Power supply circuit
7 Logic circuit
8 Input/output circuit
10, 10A Transistor region
11 Semiconductor substrate
11a First substrate portion
11b Second substrate portion
11c Surface
11d Surface
12, 12A Insulating layer
13 Source region
14 Drain region
15 Gate insulating layer
16 Gate electrode
17 Body region
18 Contact region
18a First region
18b Second region
19, 19A Drift region
19a First region
19b Second region
30 Channel region
30, 30A Semiconductor part
30a Surface
40, 41, 42 Semiconductor layer
40a Opening
41a Opening
41b Top surface
AR Active region
EIR Element isolation region
G1, G1A Trench
G2 Trench
IR1 Impurity region
IR2 Impurity region
IR2a First impurity region
IR2b Second impurity region
M, M2 Mask
T Transistor
W Lateral width

What is claimed is:

1. A semiconductor device comprising:
a semiconductor substrate having a first conductivity type;
a gate electrode positioned on the semiconductor substrate; and
a semiconductor part embedded in the semiconductor substrate and having the first conductivity type, wherein
the semiconductor substrate is provided with at least a part of a drift region being adjacent to the semiconductor part and having a second conductivity type, and
a surface of the semiconductor part and a first portion included in a surface of the drift region are positioned higher than a second portion in a surface of the semiconductor substrate, the second portion being positioned below the gate electrode.

2. The semiconductor device according to claim 1, wherein the semiconductor substrate is provided with whole of the drift region, and a drain region positioned on the first portion and having the second conductivity type.

3. The semiconductor device according to claim 1, further comprising a semiconductor layer positioned on the semiconductor substrate and having the second conductivity type, wherein
the drift region is provided across the semiconductor substrate and the semiconductor layer, and
a surface of the semiconductor layer corresponds to the first portion.

4. The semiconductor device according to claim 3, wherein the semiconductor part is embedded into an opening of the semiconductor layer.

5. The semiconductor device according to claim 1, wherein a difference between a depth of the drift region and a depth of the semiconductor part is 10% or less.

6. The semiconductor device according to claim 1, wherein an impurity concentration of the semiconductor part and an impurity concentration of the drift region are higher than an impurity concentration of the semiconductor substrate.

7. The semiconductor device according to claim 1, wherein a difference between an impurity concentration of the semiconductor part and an impurity concentration of the drift region is 10% or less.

8. The semiconductor device according to claim 1, wherein the semiconductor part is grounded.

9. The semiconductor device according to claim 1, wherein a lateral width of the semiconductor part in plan view is 0.5 μm or more and 1 μm or less.

10. A method for manufacturing a semiconductor device, the method comprising:
forming an impurity region having a second conductivity type in a semiconductor substrate having a first conductivity type;
forming a trench in a region adjacent to the impurity region in the semiconductor substrate;
embedding a semiconductor part having the first conductivity type into the trench;
forming a mask covering at least a part of the impurity region and the semiconductor part;
thinning a portion of the semiconductor substrate exposed from the mask by etching; and
forming a gate electrode on the portion of the semiconductor substrate, wherein
the impurity region corresponds to a drift region of a transistor including the gate electrode.

11. The method for manufacturing a semiconductor device according to claim 10, wherein a difference between a depth of the drift region and a depth of the semiconductor part is 10% or less.

12. The method for manufacturing a semiconductor device according to claim 10, wherein an impurity concentration of the semiconductor part and an impurity concentration of the drift region are higher than an impurity concentration of the semiconductor substrate.

13. The method for manufacturing a semiconductor device according to claim 10, wherein a difference between an impurity concentration of the semiconductor part and an impurity concentration of the drift region is 10% or less.

14. The method for manufacturing a semiconductor device according to claim 10, wherein a lateral width of the semiconductor part in plan view is 0.5 μm or more and 1 μm or less.

15. A method for manufacturing a semiconductor device, the method comprising:
forming an impurity region having a second conductivity type in a semiconductor substrate having a first conductivity type;
forming a semiconductor layer having the second conductivity type on the semiconductor substrate;
forming a trench in a region adjacent to the impurity region in the semiconductor substrate and an opening at a portion in the semiconductor layer overlapping with the trench;
embedding a semiconductor part having the first conductivity type across the trench and the opening;
forming a mask covering at least a part of a portion of the semiconductor layer overlapping with the impurity region;
removing a portion of the semiconductor layer exposed from the mask; and
forming a gate electrode on the portion of the semiconductor substrate, wherein
the impurity region corresponds to a drift region of a transistor including the gate electrode.

16. The method for manufacturing a semiconductor device according to claim 15, wherein a difference between a depth of the drift region and a depth of the semiconductor part is 10% or less.

17. The method for manufacturing a semiconductor device according to claim 15, wherein an impurity concentration of the semiconductor part and an impurity concentration of the drift region are higher than an impurity concentration of the semiconductor substrate.

18. The method for manufacturing a semiconductor device according to claim 15, wherein a difference between an impurity concentration of the semiconductor part and an impurity concentration of the drift region is 10% or less.

19. The method for manufacturing a semiconductor device according to claim 15, wherein a lateral width of the semiconductor part in plan view is 0.5 μm or more and 1 μm or less.
